(19) United States
(12) Patent Application Publication
(10) Pub. No.: US 2023/0392269 A1
(43) Pub. Date: Dec. 7, 2023

(54) Semiconductor Photoelectrode and Method for Manufacturing Same

(71) Applicant: Nippon Telegraph and Telephone Corporation, Tokyo (JP)

(72) Inventors: Yuya Uzumaki, Musashino-shi, Tokyo (JP); Takeshi Komatsu, Musashino-shi, Tokyo (JP); Akihiro Kono, Musashino-shi, Tokyo (JP); Sayumi Sato, Musashino-shi, Tokyo (JP)

(21) Appl. No.: 18/250,274

(22) PCT Filed: Nov. 20, 2020
(86) PCT No.: PCT/JP2020/043403

§ 371 Date: Apr. 24, 2023

(51) Int. Cl. C25B 11/069; C25B 11/052; C25B 9/50; C25B 11/02; C30B 25/18; C30B 29/40; C30B 33/12; C23C 14/18; C23C 14/24; C23C 14/58

(52) U.S. Cl. CPC C25B 11/069; C25B 11/052; C25B 9/50; C25B 11/02; C30B 25/18; C30B 29/406; C30B 33/12; C23C 14/18; C23C 14/24; C23C 14/5806; C23C 14/5853

(57) ABSTRACT

A semiconductor photoelectrode includes a conductive or insulating substrate, a semiconductor thin film disposed on a surface of substrate and having an uneven structure on the surface, a catalytic layer disposed along the uneven structure on the surface of semiconductor thin film, and a protective layer disposed to cover a back surface of substrate and side surfaces of substrate and semiconductor thin film.

### TECHNICAL FIELD

The present invention relates to a semiconductor photoelectrode and a method of manufacturing the semiconductor photoelectrode.

### BACKGROUND ART

A water decomposition reaction in which a photocatalyst is used includes an oxidation reaction of water and a reduction reaction of protons.
Oxidation reaction: 2H₂O+4h⁺→O₂+4H⁺
Reduction reaction: 4H⁺+4e⁻→2H₂

When an n-type photocatalytic material is irradiated with light, electrons and holes are generated and separated in the photocatalyst. Holes move to the surface of the photocatalytic material and contribute to the reduction reaction of protons. On the other hand, electrons move to a reduction electrode and contribute to the reduction reaction of protons. Ideally, such an oxidation-reduction reaction proceeds, and a water decomposition reaction arises.

A water decomposing device of the related art includes an oxidation tank and a reduction tank connected via a proton exchange membrane. An aqueous solution and an oxidation electrode are placed in an oxidation tank, and the aqueous solution and a reduction electrode are placed in the reduction tank. The protons generated in the oxidation tank diffuse to the reduction tank through the proton exchange membrane. The oxidation electrode and the reduction electrode are electrically connected by a conductive wire, and electrons move from the oxidation electrode to the reduction electrode. Light that has a wavelength which can be absorbed by the material including the oxidation electrode is emitted from a light source to cause a water decomposition reaction.

### CITATION LIST

### Non Patent Literature

Non Patent Literature 1: S. Yotsuhashi, et al., “CO2 Conversion with Light and Water by GaN Photoelectrode”, Japanese Journal of Applied Physics 51 (2012) 02BP07

### SUMMARY OF INVENTION

### Technical Problem

For example, when a gallium nitride thin film grown on a sapphire substrate is used as an oxidation electrode and the gallium nitride thin film is irradiated with light in an aqueous solution, oxygen is generated on the surface of the gallium nitride. An amount of generated oxygen depends on a number of holes generated and separated in a semiconductor, as described in the above-described oxidation reaction formula. Therefore, an improvement in efficiency can be expected by increasing a light irradiation area (a reaction field) of the semiconductor.

A process of generating oxygen mainly includes (1) adsorption of water to the reaction field, (2) dissociation of a O—H bond, (3) binding of adsorbed oxygen, and (4) separation of oxygen from the reaction field. In order to promote the reaction efficiency, it is necessary to improve a reaction rate in each of the steps (1) to (4). In order to promote the oxygen generation reaction, for example, NiO is formed as a catalyst material on the semiconductor surface. However, much of the catalyst material contributes little to the promotion of the step of (4), the finally generated oxygen covers the reaction field without being separated from the surface, and thus there is a problem that the improvement in efficiency is inhibited due to catalyst formation.

The present invention has been made in view of the circumstances and an objective of the present invention is to improve light energy conversion efficiency of a semiconductor photoelectrode that causes an oxidation-reduction reaction through light irradiation.

### Solution to Problem

A semiconductor photoelectrode according to an aspect of the present invention is a semiconductor photoelectrode that fulfills a catalytic function through light irradiation to cause an oxidation-reduction reaction. The semiconductor photoelectrode includes: a conductive or insulating substrate; a semiconductor thin film disposed on a surface of the substrate and having an uneven structure; a catalytic layer disposed along the uneven structure of the semiconductor thin film; and a protective layer disposed to cover a back surface of the substrate and side surfaces of the substrate and the semiconductor thin film.

A method of manufacturing a semiconductor photoelectrode according to another aspect of the present invention is a method of manufacturing a semiconductor photoelectrode that fulfills a catalytic function through light irradiation to cause an oxidation-reduction reaction. The method includes: a step of forming a semiconductor thin film on a surface of a conductive or insulating substrate; a step of forming an uneven structure on a surface of the semiconductor thin film by etching; a step of forming a catalytic layer along the uneven structure on the surface of the semiconductor thin film; a step of performing heat treatment on the semiconductor thin film and the catalytic layer; and a step of forming a protective layer to cover a back surface of the substrate and side surfaces of the substrate and the semiconductor thin film.

### Advantageous Effects of Invention

According to the present invention, it is possible to improve the photoenergy conversion efficiency of the semiconductor photoelectrode that causes an oxidation-reduction reaction through light irradiation.

### BRIEF DESCRIPTION OF DRAWINGS

FIG. 1 is a cross-sectional view illustrating an example of a configuration of a semiconductor photoelectrode according to the present embodiment.

FIG. 2 is a flowchart illustrating an example of a method of manufacturing the semiconductor photoelectrode according to the present embodiment.

FIG. 3 is a cross-sectional view illustrating an example of a surface shape of a semiconductor thin film.

FIG. 4 is a cross-sectional view illustrating an example of a configuration of a semiconductor photoelectrode according to a comparative example.

FIG. 5 is a diagram illustrating an example of an apparatus that performs an oxidation-reduction reaction test.

FIG. 6A is a diagram illustrating a state in which a gas is generated on a flat surface.

FIG. 6B is a diagram illustrating a state in which a gas is generated on an uneven surface and is separated.

### DESCRIPTION OF EMBODIMENTS

Hereinafter, an embodiment of the present invention will be described with reference to the drawings. The present invention is not limited to the embodiments to be described below, and modifications may be made without departing from the gist of the present invention.

### Configuration of Semiconductor Photoelectrode

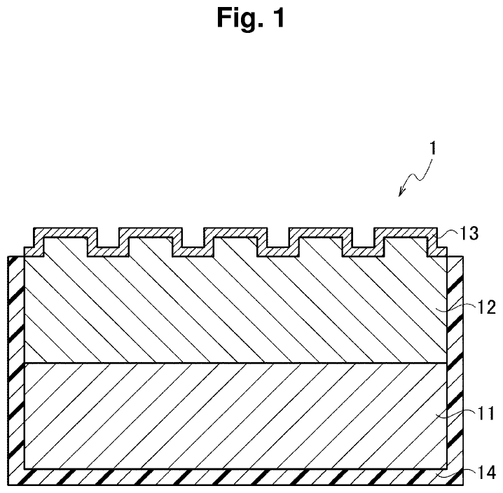

FIG. 1 is a cross-sectional view illustrating an example of a configuration of a semiconductor photoelectrode according to the present embodiment. The semiconductor photoelectrode 1 fulfills a catalytic function through light irradiation in an aqueous solution to cause an oxidation-reduction reaction. The semiconductor photoelectrode 1 illustrated in the drawing includes an insulating or conductive substrate 11, a semiconductor thin film 12 disposed on a surface of the substrate 11 and provided with an uneven structure on a surface opposite to the substrate 11, a catalytic layer 13 disposed along the uneven structure of the semiconductor thin film 12, and a protective layer 14 formed to cover a back surface of substrate 11 and side surfaces of the substrate 11 and the semiconductor thin film 12.

As the substrate 11, for example, an insulating or conductive substrate such as a sapphire substrate, a GaN substrate, a glass substrate, or a Si substrate can be used.

The semiconductor thin film 12 has a photocatalytic function of causing a reaction of a target substance through light irradiation. As the semiconductor thin film 12, for example, a metal oxide such as gallium nitride (GaN), titanium oxide (TiO₂), tungsten oxide (WO₃), or gallium oxide (Ga₂O₃), or a compound semiconductor such as tantalum nitride (Ta₃N₅) or cadmium sulfide (CdS) can be used.

The semiconductor thin film 12 has an uneven structure on a surface (a surface opposite to the substrate 11). The uneven structure has, for example, a lattice form or a stripe form. A width and a depth of the recess may be determined so that as the effect of releasing bubbles of a product gas can be obtained. For example, in view of a typical bubble size of the generated gas, the width of the recess is preferably equal to or less than 20 μm, and the depth is preferably equal to or less than 1 μm. When the depth is greater than 1 μm, the gas is trapped and the gas releasing effect is impaired.

As the catalytic layer 13, a material that has a cocatalyst function for the semiconductor thin film 12 is used. As the catalytic layer 13, for example, one or more metals of Ni, Co, Cu, W, Ta, Pd, Ru, Fe, Zn, and Nb, or an oxide of a metal can be used. The thickness of the catalytic layer 13 is desirably 1 nm to 10 nm, and particularly desirably in the range from 1 nm to 3 nm in which sufficient light is able to be transmitted. The catalytic layer 13 may cover the entire surface exposed portion or only a part of the semiconductor thin film 12. When the catalytic layer 13 covers only a part of the semiconductor thin film 12, for example, the catalytic layer 13 may cover only the recess portion or the protrusion portion of the uneven structure or may cover only a part of the uneven structure on the surface of the semiconductor thin film 12.

The protective layer 14 is a layer for preventing deterioration due to a contact between the substrate 11 and the aqueous solution of the semiconductor thin film 12. For the protective layer 14, an insulating material such as an epoxy resin that does not react with an aqueous solution, the substrate 11, and the semiconductor thin film 12 is used.

### Method of Manufacturing Semiconductor Photoelectrode

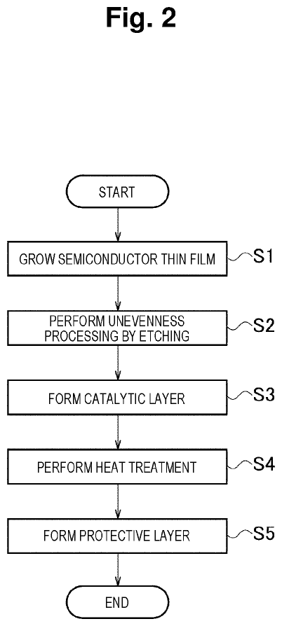

A method of manufacturing a semiconductor photoelectrode will be described with reference to FIG. 2.

In step S11, the semiconductor thin film 12 is grown on the substrate 11.

In step S12, unevenness processing is performed on the surface of the semiconductor thin film 12 by etching. Examples of surface processing schemes include etching, cutting, and pressing. The semiconductor thin film 12 is thin and easily cracked. Since the light absorption characteristics affects the quality of crystallinity of a layer, etching that is highly accurate non-contact processing is preferable.

In step S13, the catalytic layer 13 is formed on the uneven surface of the semiconductor thin film 12. The catalytic layer 13 is formed with a constant thickness along the uneven structure of semiconductor thin film 12. The catalytic layer 13 may be formed to cover the entire surface of the semiconductor thin film 12, the catalytic layer 13 may be formed to cover only a part of the surface of the semiconductor thin film 12, or the catalytic layer 13 may be formed only in the recess portion or only in the protrusion portion.

In step S14, a sample in which the semiconductor thin film 12 and the catalytic layer 13 are formed on the substrate 11 is subjected to heat treatment. The heat treatment may be performed on a hot plate or may be performed in an electric furnace.

In step S15, the protective layer 14 is formed to cover the surface of the semiconductor thin film 12 excluding the uneven surface, that is, the back surface and the side surface of the substrate 11 and the side surface of the semiconductor thin film 12.

### Examples of Semiconductor Photoelectrode

A semiconductor photoelectrode in Examples 1 to 4 in which the material of the substrate and the size of the uneven structure were changed was produced, and an oxidation-reduction reaction test to be described below was performed. Hereinafter, the semiconductor photoelectrode in Examples 1 to 4 will be described.

### Example 1

In the semiconductor photoelectrode of Example 1, a semiconductor thin film is subjected to unevenness processing such that the surface area of the semiconductor photoelectrode is about 1.5 times the sample area. A sapphire substrate was used.

In step S11, an n-GaN semiconductor thin film was epitaxially grown on the sapphire substrate by metal organic chemical vapor deposition (MOCVD) to form a semiconductor thin film as a light absorbing layer (a layer that absorbs light and produces electrons and holes). As a growth raw material, an ammonia gas and trimethylgallium were used. Hydrogen was used as a carrier gas to be sent into a growth furnace. The film thickness of the n-GaN semiconductor thin film was 2 μm with which light was sufficiently absorbed. The carrier density was 3×10¹⁸ cm⁻³.

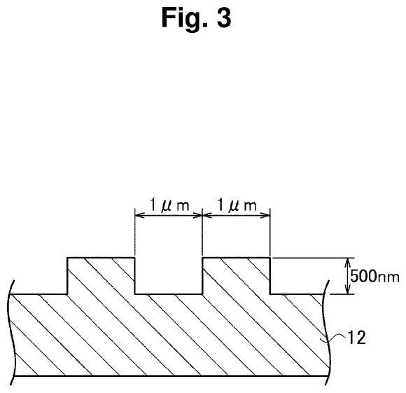

In step S12, a resist was applied to the surface of the n-GaN semiconductor thin film. As illustrated in the cross-sectional view of FIG. 3, the surface of the n-GaN semiconductor thin film was processed with a thickness of 500 nm by dry etching. An uneven pattern had a stripe from, a pattern dimension was 1 μm, and a pattern pitch was 2 μm. Thereafter, the resist was removed to form an uneven pattern on the surface of the n-GaN semiconductor thin film. The cross section of the sample was observed with an SEM to confirm that the size of the uneven structure was formed as intended, and it was calculated from each dimension that the surface area was increased about 1.5 times as compared to that before processing. The sample area is 1 cm², and the surface area is 1.5 cm².

In step S13, Ni that has a thickness of about 1 nm was vacuum-deposited along the uneven structure on the surface of the n-GaN semiconductor thin film.

In step S14, this sample was subjected to heat treatment in the air at 300° C. for 1 hour to form NiO. When the cross section of the sample was observed by a TEM, the film thickness of NiO was 2 nm.

In step S15, a protective layer was formed using an epoxy resin to cover the back surface of the sapphire substrate (the surface on which the n-GaN semiconductor thin film was not formed) and the side surfaces of the sapphire substrate and the n-GaN semiconductor thin film.

A semiconductor photoelectrode in Example 1 was obtained through the foregoing steps.

### Example 2

In the semiconductor photoelectrode of Example 2, a semiconductor thin film is subjected to unevenness processing such that a surface area of the semiconductor photoelectrode is about 1.5 times a sample area. This example differs from Example 1 in that an n-GaN substrate is used.

In Example 2, in step S11, an n-GaN semiconductor thin film was epitaxially grown on an n-GaN substrate by MOCVD. As a growth raw material, an ammonia gas and trimethylgallium were used. Hydrogen was used as a carrier gas to be sent into a growth furnace. The film thickness of the n-GaN semiconductor thin film was 2 μm with which light was sufficiently absorbed. The carrier density was 3×10¹⁸ cm⁻³.

Steps in step S12 and subsequent steps were performed in the same way as in Example 1.

### Example 3

In the semiconductor photoelectrode in Example 3, a semiconductor thin film was subjected to unevenness processing such that the surface area of the semiconductor photoelectrode was about twice the sample area.

Example 3 differs from Example 1 in that a surface of an n-GaN semiconductor thin film was processed with a thickness of 500 nm with a pattern dimension of 0.5 μm and at a pattern pitch of 1 μm by dry etching in step S12. The other points are the same as in Example 1.

In Example 3, the surface area increased about twice as compared to that before the processing. The sample area is 1 cm² and the surface area is 2 cm².

### Example 4

In the semiconductor photoelectrode of Example 4, a semiconductor thin film was subjected to unevenness processing such that the surface area of the semiconductor photoelectrode was about 2.5 times the sample area.

Example 4 differs from Example 1 in that in step S12, the surface of the n-GaN semiconductor thin film was processed with 500 nm at a pattern dimension of 0.3 μm, a pattern pitch of 0.6 μm, and by dry etching. The other points are the same as in Example 1.

In Example 4, the surface area increased about 2.5 times as compared to that before processing. The sample area is 1 cm² and the surface area is 2.5 cm².

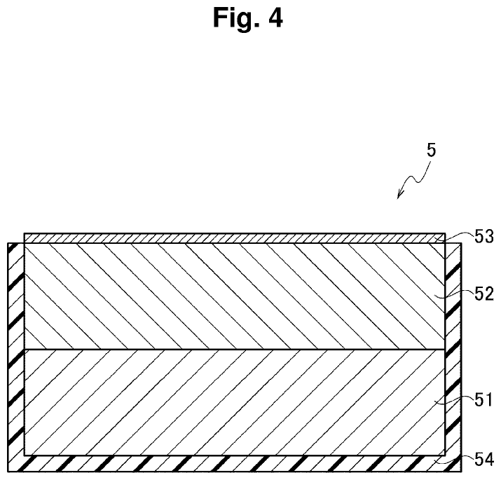

Next, Comparative Examples 1 to 5 will be described. In Comparative Examples 1 to 5, the surface of the semiconductor photoelectrode is not uneven structure but flat. FIG. 4 is a cross-sectional view of a semiconductor photoelectrode 5 according to Comparative Examples 1 to 5. The semiconductor photoelectrode 5 illustrated in the drawing includes an insulating or conductive substrate 51, a semiconductor thin film 52 disposed on a front surface of substrate 51 and having a flat front surface, a catalytic layer 53 disposed on a front surface of semiconductor thin film 52, and a protective layer 54 formed to cover a back surface of substrate 51 and side surfaces of the substrate 51 and the semiconductor thin film 52. The semiconductor photoelectrode 5 in FIG. 4 differs from the semiconductor photoelectrode 1 in FIG. 1 in that an uneven structure is not provided on the surface of the semiconductor thin film 52 and the surface is flat.

### Comparative Example 1

In the semiconductor photoelectrode of Comparative Example 1, the surface of the semiconductor photoelectrode is flat without performing unevenness processing on the semiconductor thin film. The sample area and the surface area are both 1 cm². A sapphire substrate was used.

Comparative Example 1 differs from Example 1 in that a semiconductor photoelectrode was produced without performing step S12. The other points are the same as in Example 1. The cross section of the sample was observed by an SEM/TEM, and it was confirmed that the semiconductor thin film and the catalytic layer had a flat structure.

### Comparative Example 2

In the semiconductor photoelectrode of Comparative Example 2, the surface of the semiconductor photoelectrode is flat without performing unevenness processing on the semiconductor thin film. The sample area and the surface area are both 1 cm². An n-GaN substrate was used.

Comparative Example 2 differs from Example 2 in that a semiconductor photoelectrode is produced without performing the step of step S12. The other points are the same as in Example 2.

### Comparative Example 3

In the semiconductor photoelectrode of Comparative Example 3, the surface of the semiconductor photoelectrode is flat without performing unevenness processing on the semiconductor thin film. The sample area and the surface area are both 1.5 cm². The surface area was the same as in Example 1. A sapphire substrate was used.

Comparative Example 3 differs from Example 1 in that a semiconductor photoelectrode was produced without performing step S12. The other points are the same as in Example 1.

### Comparative Example 4

In the semiconductor photoelectrode of Comparative Example 4, the surface of the semiconductor photoelectrode is flat without performing unevenness processing on the semiconductor thin film. The sample area and the surface area are both 2 cm². The surface area was the same as in Example 3. A sapphire substrate was used.

Comparative Example 4 differs from Example 3 in that a semiconductor photoelectrode was produced without performing step S12. The other points are the same as in Example 3.

### Comparative Example 5

In the semiconductor photoelectrode of Comparative Example 5, the surface of the semiconductor photoelectrode is flat without performing unevenness processing on the semiconductor thin film. The sample area and the surface area are both 2.5 cm². The surface area was the same as in Example 4. A sapphire substrate was used.

Comparative Example 5 differs from Example 4 in that a semiconductor photoelectrode was produced without performing step S12. The other points are the same as in Example 4.

### Oxidation-Reduction Reaction Test

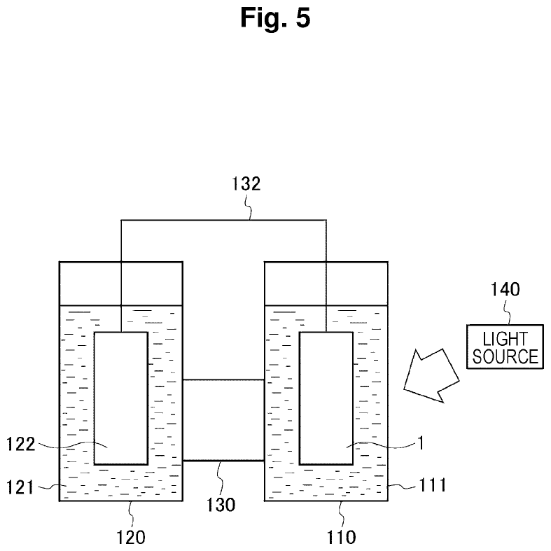

In Examples 1 to 4 and Comparative Examples 1 to 5, the oxidation-reduction reaction test was performed using an apparatus in FIG. 5.

The apparatus in FIG. 5 includes an oxidation tank 110 and a reduction tank 120. The aqueous solution 111 is put in the oxidation tank 110, and the semiconductor photoelectrode 1 of Examples 1 to 4 or the semiconductor photoelectrode 5 of Comparative Examples 1 to 5 is put in the aqueous solution 111 as an oxidation electrode. An aqueous solution 121 is put into the reduction tank 120, and the reduction electrode 122 is put into the aqueous solution 121.

A 1 mol/l sodium hydroxide aqueous solution was used as the aqueous solution 111 of the oxidation tank 110. As the aqueous solution 111, a potassium hydroxide aqueous solution or hydrochloric acid may be used. When the oxidation electrode 112 is formed of gallium nitride, an alkaline aqueous solution is preferable.

A 0.5 mol/l potassium hydrogen carbonate aqueous solution was used as the aqueous solution 121 of the reduction tank 120. As the aqueous solution 121, a sodium bicarbonate aqueous solution, a potassium chloride aqueous solution, or a sodium chloride aqueous solution may be used.

Platinum (manufactured by Nilaco Corporation) was used for the reduction electrode 122. The reduction electrode 122 may be a metal or a metal compound. As the reduction electrode 122, for example, nickel, iron, gold, silver, copper, indium, or titanium may be used.

The oxidation tank 110 and the reduction tank 120 are connected via a proton film 130. The protons generated in the oxidation tank 110 diffuse to the reduction tank 120 via the proton film 130. Nafion (registered trademark) was used for the proton film 130. Nafion is a perfluorocarbon material composed of a hydrophobic Teflon skeleton composed of carbon-fluorine and a perfluoro side chain having a sulfonic acid group.

The oxidation electrode 112 and the reduction electrode 122 are electrically connected by a conductive wire 132, and electrons move from the oxidation electrode 112 to the reduction electrode 122.

As the light source 140, a high pressure xenon lamp (illuminance: 5 mW/cm²) of 300 W was used. The light source 140 may to be able to emit light having a wavelength that can be absorbed by the material of which the semiconductor photoelectrode provided as the oxidation electrode is formed. For example, in an oxidation electrode formed of gallium nitride, the absorbable wavelength is a wavelength equal to or less than 365 nm. As the light source 140, a light source such as a xenon lamp, a mercury lamp, a halogen lamp, a pseudo sunlight source, or sunlight may be used, or these light sources may be combined.

In the oxidation-reduction reaction test, for each of the semiconductor photoelectrode of Examples 1 to 4 and the semiconductor photoelectrode of Comparative Examples 1 to 5, an n-GaN semiconductor thin film was scratched, a conductive wire was connected to a part of the surface, soldering was performed using indium, and coating was performed with an epoxy resin so that the indium surface was not exposed.

In the oxidation-reduction reaction test, a nitrogen gas was caused to flow at 10 ml/min in each reaction tank, a light irradiation area of the sample was set to 1 cm² (in the case of Example 1, the surface area was 1.5 cm².), and the aqueous solutions 111 and 121 were stirred at the center position of the bottom of each reaction tank at a rotation speed of 250 rpm using a stirrer and a stirrer.

After the inside of the reaction tank was sufficiently replaced with nitrogen gas, the light source 140 was fixed to face the surface of a test target semiconductor photoelectrode on which NiO was formed, and the semiconductor photoelectrode was uniformly irradiated with light.

After 10 hours from light irradiation, the gas in each reaction tank was collected, and a reaction product was analyzed through gas chromatography. As a result, it was confirmed that oxygen was generated in the oxidation tank 110 and hydrogen was generated in the reduction tank 120. By changing the metal of the reduction electrode to, for example, Ni, Fe, Au, Pt, Ag, Cu, In, Ti, Co, or Ru, or by changing an atmosphere in a cell, it is also possible to generate a carbon compound through the reduction reaction of carbon dioxide and to generate ammonia through the reduction reaction of nitrogen.

### Experimental Result

The production amounts of oxygen and hydrogen gases with respect to a light irradiation time in Examples 1 to 4 and Comparative Examples 1 to 5 are shown in Table 1. The amount of each produced gas was normalized with the surface area of the semiconductor photoelectrode.

TABLE 1

| | | | | | | Amount of generated | |
|---|---|---|---|---|---|---|---|
| | | | | | | gas in cell (μmol · h⁻¹) | |
| | | | | Sample | Surface | After light irradiation | |
| | | Semiconductor | | area | area | of 10 hours | |
| Sample | Substrate | thin film | Etching | (cm²) | (cm²) | oxygen | hydrogen |
| Example 1 | Sapphire | n-GaN | Yes | 1 | 1.5 | 18 | 36 |
| Example 2 | n-GaN | n-GaN | Yes | 1 | 1.5 | 19 | 36 |
| Example 3 | Sapphire | n-GaN | Yes | 1 | 2 | 25 | 49 |
| Example 4 | Sapphire | n-GaN | Yes | 1 | 2.5 | 31 | 61 |
| Comparative | Sapphire | n-GaN | No | 1 | 1 | 6 | 12 |
| Example 1 | | | | | | | |
| Comparative | n-GaN | n-GaN | No | 1 | 1 | 7 | 13 |
| Example 2 | | | | | | | |
| Comparative | Sapphire | n-GaN | No | 1.5 | 1.5 | 11 | 22 |
| Example 3 | | | | | | | |
| Comparative | Sapphire | n-GaN | No | 2 | 2 | 14 | 28 |
| Example 4 | | | | | | | |
| Comparative | Sapphire | n-GaN | No | 2.5 | 2.5 | 18 | 37 |
| Example 5 | | | | | | | |

It was understood that in all Examples 1 to 4 and Comparative Examples 1 to 5, oxygen and hydrogen are produced during light irradiation.

In Example 1, the amount of generated gas was greater than in Comparative Example 1. Similarly, in Example 2, the amount of generated gas was greater than that in Comparative Example 2. It is considered that this is because an increase in a reaction field and desorption of the generated gas are promoted by forming the surface of the semiconductor photoelectrode as an uneven structure.

When Examples 1, 3, and 4 in which surface areas were different were compared, it was understood that the larger the surface area was, the greater the gas generation amount was. In Comparative Examples 3, 4, and 5, the larger the surface area was, the greater the gas generation amount was. It is considered that the increase in the reaction field due to the increase in the surface area of the semiconductor photoelectrode had an effect on the amount of generated gas.

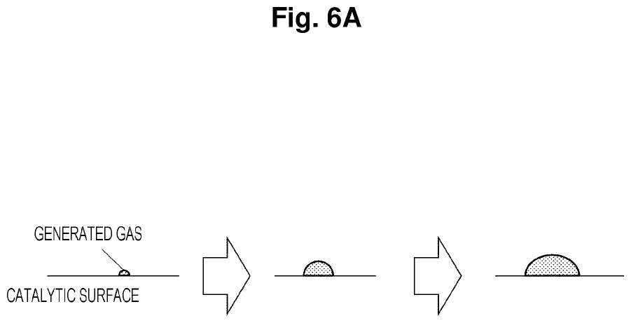

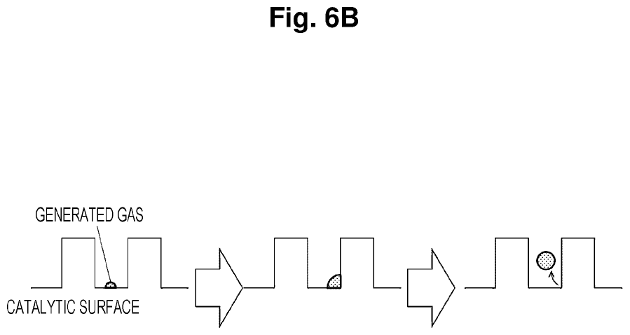

When Example 1 and Comparative Example 3 in which the surface area was the same were compared, the amount of generated gas in Example 1 in which an uneven structure is provided on the surface was greater than that in Comparative Example 3 in which the surface was flat. When Example 3 was compared to Comparative Example 4 and Example 4 was compared to Comparative Example 5, the amount of generated gas in Examples 3 and 4 in which the structure was uneven was greater than that in Comparative Examples 4 and 5. It is considered that promotion of gas separation due to the uneven structure of the surface of the semiconductor photoelectrode had an effect on the amount of generated gas. The separation of the produced gas depends on a surface tension of the surface of the semiconductor photoelectrode. As illustrated in FIGS. 6A and 6B, the surface tension can be reduced and the separation of the produced gas is promoted by providing the uneven structure on the surface rather than the flat surface.

As described above, the semiconductor photoelectrode 1 according to the present embodiment includes the conductive or insulating substrate 11, the semiconductor thin film 12 disposed on the front surface of substrate 11 and having an uneven structure on the front surface, the catalytic layer 13 disposed along the uneven structure on the front surface of semiconductor thin film 12, and the protective layer 14 disposed to cover the back surface of substrate 11 and the side surfaces of substrate 11 and the semiconductor thin film 12. By making the surface of the semiconductor photoelectrode 1 uneven, the reaction field is increased, and the separation of the generated gas is promoted. Therefore, the amount of gas generated by the oxidation-reduction reaction can be increased, that is, the light energy conversion efficiency can be improved.

### REFERENCE SIGNS LIST

1 Semiconductor photoelectrode
11 Substrate
12 Semiconductor thin film
13 Catalytic layer
14 Protective layer

1. A semiconductor photoelectrode that fulfills a catalytic function through light irradiation to cause an oxidation-reduction reaction, the semiconductor photoelectrode comprising:
a conductive or insulating substrate;
a semiconductor thin film disposed on a surface of the substrate and having an uneven structure;
a catalytic layer disposed along the uneven structure of the semiconductor thin film; and
a protective layer disposed to cover a back surface of the substrate and side surfaces of the substrate and the semiconductor thin film.

2. The semiconductor photoelectrode according to claim 1,
wherein the catalytic layer is disposed to cover the entire surface of the semiconductor thin film.

3. The semiconductor photoelectrode according to claim 1,
wherein the catalytic layer is disposed to cover a part of a surface of the semiconductor thin film.

4. The semiconductor photoelectrode according to claim 1,
wherein the semiconductor thin film is an n-type semiconductor.

5. A method of manufacturing a semiconductor photoelectrode that fulfills a catalytic function through light irradiation to cause an oxidation-reduction reaction, the method comprising:
a step of forming a semiconductor thin film on a surface of a conductive or insulating substrate;
a step of forming an uneven structure on a surface of the semiconductor thin film by etching;
a step of forming a catalytic layer along the uneven structure on the surface of the semiconductor thin film;
a step of performing heat treatment on the semiconductor thin film and the catalytic layer; and
a step of forming a protective layer to cover a back surface of the substrate and side surfaces of the substrate and the semiconductor thin film.

6. The semiconductor photoelectrode according to claim 2,
wherein the semiconductor thin film is an n-type semiconductor.

7. The semiconductor photoelectrode according to claim 3,
wherein the semiconductor thin film is an n-type semiconductor.
